(19) United States
(12) Patent Application Publication
(10) Pub. No.: US 2023/0090580 A1
(43) Pub. Date: Mar. 23, 2023

(54) PHOTOSENSITIVE RESIN COMPOSITION, SHAPED PRODUCT, METHOD FOR MANUFACTURING SHAPED PRODUCT AND METHOD FOR MANUFACTURING LIQUID DISCHARGE HEAD

(71) Applicant: CANON KABUSHIKI KAISHA, Tokyo (JP)

(72) Inventors: Miho Ishii, Kanagawa (JP); Kazunari Ishizuka, Shizuoka (JP); Satoshi Tsutsui, Kanagawa (JP); Yohei Hamade, Tokyo (JP); Haruka Yamaji, Tokyo (JP); Hikaru Sugimoto, Kanagawa (JP)

(21) Appl. No.: 17/813,704

(22) Filed: Jul. 20, 2022

(30) Foreign Application Priority Data
Jul. 28, 2021 (JP) 2021-123199

(51) Int. Cl. G03F 7/038; G03F 7/004; G03F 7/40

(52) U.S. Cl. CPC G03F 7/0385; G03F 7/0382; G03F 7/0048; G03F 7/40

(57) ABSTRACT

A photosensitive resin composition comprising: (a) an epoxy resin, (b) a cationic polymerization initiator, (c) an anthracene derivative, and (d) an organic solvent having a carbonyl group, wherein the anthracene derivative (c) comprises at least one selected from the group consisting of compounds represented by a following formula (1) (In the formula (1), R¹ and R² each independently represents an alkyl group having 4 or more carbon atoms or an aryl group having 6 to 10 carbon atoms, R³ and R⁴ each independently represents an alkyl group, an alkoxy group having 4 or more carbon atoms, an amino group, an alkylamino group, an alkylsulfonyl group, or a halogen atom, and m and n each independently represents an integer of 0 to 4).

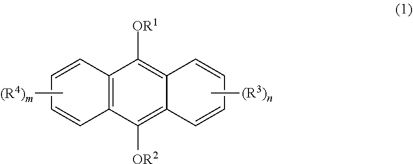

### BACKGROUND OF THE INVENTION

### Field of the Invention

The present disclosure relates to a photosensitive resin composition and methods for manufacturing a shaped product and a liquid discharge head by using the photosensitive resin composition.

### Description of the Related Art

Currently, photosensitive resin compositions are widely used in fields such as coatings, inks, and electronic materials. Since the polymerization of photosensitive resin compositions is polymerized by active light such as ultraviolet rays and visible light, such compositions excel in that the polymerization is faster than that of a thermosetting resin, and the amount of organic solvent used can be significantly reduced, so that working environment can be improved and load on environment can be reduced. Further, it is possible to form a fine structure by using a photolithography technique, and one example thereof is application to a liquid discharge head.

When the wavelength of irradiation in an exposure apparatus used for photolithography irradiating is a general i-line (365 nm), where a photosensitive resin composition comprising an epoxy resin and a cationic polymerization initiator having an absorption wavelength at the i-line is used, the composition functions as a perfect negative type resist. Even when a cationic polymerization initiator having no absorption wavelength at the i-line is used, patterning is possible by using the polymerization initiator in combination with a sensitizer having an absorption wavelength at the i-line.

Various examples of the sensitizer include naphthalene derivatives, anthracene derivatives, anthraquinone derivatives, thioxanthone derivatives, and the like. Since these sensitizers have a plurality of aromatic rings, a photosensitive resin layer having increased Tg, increased hardness, and reduced thermal swelling rate can be obtained. In particular, anthracene and derivatives thereof have high absorption at the i-line and can be suitably used. Japanese Patent Application Publication No. 2008-256980 discloses that a high sensitizing effect can be obtained by comprising anthracene as a sensitizer.

### SUMMARY OF THE INVENTION

When a photosensitive resin composition is used as a resist material, a carbonyl group-containing solvent is commonly used as a coating solvent from the viewpoint of solubility and coatability. However, carbonyl group-containing solvents may generate a peroxide during storage, and there is a concern that depending on the structure of the sensitizer used, the sensitizer may be decomposed. Therefore, in the related art, it is difficult to achieve both curability and storage stability of a photosensitive resin composition using a carbonyl group-containing solvent.

The present disclosure provides a photosensitive resin composition having excellent storage stability while maintaining curability, and also provides methods for manufacturing a shaped product and a liquid discharge head by using the photosensitive resin composition.

The present disclosure relates to a photosensitive resin composition comprising:
(a) an epoxy resin,
(b) a cationic polymerization initiator,
(c) an anthracene derivative, and
(d) an organic solvent having a carbonyl group, wherein
the anthracene derivative (c) comprises at least one selected from the group consisting of compounds represented by a following formula (1).

(In the formula (1), R¹ and R² each independently represents an alkyl group having 4 or more carbon atoms or an aryl group having 6 to 10 carbon atoms, R³ and R⁴ each independently represents an alkyl group, an alkoxy group having 4 or more carbon atoms, an amino group, an alkylamino group, an alkylsulfonyl group, or a halogen atom, and m and n each independently represents an integer of 0 to 4).

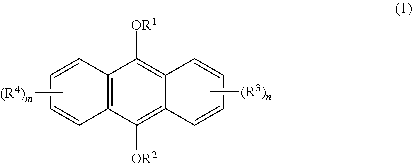

According to the present disclosure, it is possible to provide a photosensitive resin composition having excellent storage stability while maintaining curability.

Further features of the present invention will become apparent from the following description of exemplary embodiments with reference to the attached drawings.

### BRIEF DESCRIPTION OF THE DRAWINGS

FIGS. 1A to 1C illustrates an example of a method for manufacturing a shaped product using a photosensitive resin composition;

FIGS. 2A and 2B are schematic diagrams of an inkjet recording head using a photosensitive resin composition; and

FIGS. 3A to 3H illustrates an example of a method for manufacturing an inkjet recording head using a photosensitive resin composition.

### DESCRIPTION OF THE EMBODIMENTS

In the present disclosure, the expression of “from XX to YY” or “XX to YY” indicating a numerical range means a numerical range including a lower limit and an upper limit which are end points, unless otherwise specified. Also, when a numerical range is described in a stepwise manner, the upper and lower limits of each numerical range can be arbitrarily combined. In the following description, the same number is assigned in the figures to structures that have the same function, and in some instances a description thereof may be omitted.

Component (a): Epoxy Resin

The photosensitive resin composition comprises an epoxy resin as the component (a). The epoxy resin is preferably a cationically polymerized epoxy resin in consideration of the adhesion performance, mechanical strength, swelling resistance, reactivity as a photolithography material, resolution, and the like of the cured product.

More specific examples can include cationically polymerized epoxy resin such as at least one polyfunctional epoxy resin selected from the group consisting of an epoxy resin having an alicyclic skeleton, an epoxy resin having a bisphenol skeleton such as bisphenol A type or F type epoxy resin, an epoxy resin having a phenol-novolac skeleton such as a phenol-novolac epoxy resin, an epoxy resin having a cresol-novolak skeleton such as a cresol-novolak epoxy resin, an epoxy resin having a norbornene skeleton, an epoxy resin having a terpene skeleton, an epoxy resin having a dicyclopentadiene skeleton, an epoxy resin having an oxycyclohexane skeleton, and the like. These can be used alone or in combination of two or more.

An epoxy resin having two or more epoxy groups, that is, a bi- or higher functional epoxy resin is preferably used as the epoxy resin. As a result, the cured product is three-dimensionally crosslinked, and the desired curability can be obtained. It is more preferable to use a tri- or higher functional epoxy resin having three or more epoxy groups. Further, at least one of the bifunctional epoxy resins may be added to and used with the tri- or higher functional epoxy resin. That is, it is preferable that the epoxy resin comprise a tri- or higher functional epoxy resin and a bifunctional epoxy resin. As such an epoxy resin, a commercially available one can also be used.

Examples of commercially available tri- or higher functional epoxy resins include “157S70” and “jER1031S” (trade names) manufactured by Mitsubishi Chemical Corp., “EPICLON N695” and “EPICLON N-865” (trade names) manufactured by DIC Corporation, “CELLOXIDE 2021”, “GT-300 series”, “GT-400 series”, “EHPE3150” (trade names), manufactured by Daicel Corporation, “SU8” (trade name) manufactured by Nippon Kayaku Co., Ltd., “VG3101” (trade name) and “EPDX-MKR1710” (trade name) manufactured by Printec Corporation, “Denacol Series” manufactured by Nagase ChemteX Corporation, and the like.

Examples of commercially available bifunctional epoxy resins include “jER1004”, “jER1007”, “jER1009”, “jER1009F”, “jER1010”, “jER1256” (trade names) manufactured by Mitsubishi Chemical Corp., “EPICLON 4050” and “EPICLON 7050” (trade names) manufactured by DIC Corporation, and the like.

Component (b): Cationic Polymerization Initiator

The photosensitive resin composition comprises a cationic polymerization initiator as the component (b). The cationic polymerization initiator preferably has a cationic moiety and an anionic moiety. The cationic polymerization initiator is preferably at least one selected from the group consisting of sulfonic acid compounds, diazomethane compounds, sulfonium salt compounds, iodonium salt compounds, disulfone-based compounds, and the like. From the viewpoint of reactivity at the time of i-line irradiation, at least one selected from the group consisting of sulfonium salt compounds and iodonium salt compounds is more preferable, and at least one selected from the group consisting of sulfonium salt compounds is further preferable. That is, it is preferable that the cation moiety include at least one selected from the group consisting of a sulfonium salt and an iodonium salt.

An onium salt compound preferably includes at least one selected from the group consisting of SbF₆⁻, AsF₆⁻, PF₆⁻, (Rf)ₙPF₆₋ₙ⁻ (Rf is a perfluoroalkyl group), BF₄⁻, B(C₆F₅)₄⁻ and the like as the anion moiety. From the viewpoint of adhesion to a substrate plate, in particular, polymerization initiators including an antimony-containing compound, that is, SbF₆⁻ are more preferable. These can be used alone or in a combination of two or more. Commercially available cationic polymerization initiators can also be used.

Commercially available products include “ADEKA OPTOMER SP-170”, “ADEKA OPTOMER SP-172”, and “SP-150” (trade names) manufactured by Adeka Corporation, “CPI-410S”, “CPI-110A”, and “CPI-100P” (trade names) manufactured by San-Apro Ltd., “DTS-102”, “DTS-200”, “BBI-103”, and “BBI-102” (trade names) manufactured by Midori Kagaku Co., Ltd, “IBPF”, “IBCF”, “TS-01”, and “TS-91” (trade names) manufactured by Sanwa Chemical Co., Ltd., “WPI-116” and “WPI-124” (trade names) manufactured by FUJIFILM Wako Chemicals Co., Ltd., “Omnicat 250” (trade name) manufactured by IGM Resins B. V., and the like.

It is preferable to use at least one selected from the group consisting of “CPI-410S”, “CPI-110A”, “DTS-102”, “DTS-200”, “ADEKA OPTOMER SP-172”, “Omnicat 250”, “WPI-116”, and “WPI-124”.

From the viewpoint of curability and adhesion to a substrate, the amount of the cationic polymerization initiator, which is the component (b), in the photosensitive resin composition is preferably from 0.1 to 30 parts by mass, more preferably from 0.5 to 15 parts by mass, and even more preferably from 1 to 10 parts by mass per 100 parts by mass of the solid fraction of the epoxy resin, which is the component (a).

Component (c): Anthracene Derivative

The photosensitive resin composition comprises an anthracene derivative as the component (c). The anthracene derivative includes at least one selected from the group consisting of the compounds represented by the following formula (1).

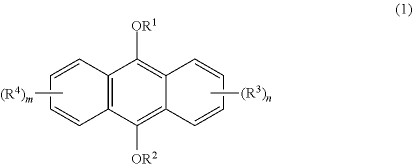

In the formula (1), R¹ and R² each independently represents an alkyl group having 4 or more carbon atoms (preferably from 4 to 18 carbon atoms, and more preferably from 4 to 12 carbon atoms) or an aryl group (preferably a phenyl group) having from 6 to 10 carbon atoms, R³ and R⁴ each independently represents an alkyl group (preferably having from 1 to 4 carbon atoms, and more preferably 1 or 2 carbon atoms), an alkoxy group having 4 or more carbon atoms (preferably from 4 to 18 carbon atoms, more preferably from 4 to 12 carbon atoms, even more preferably from 4 to 8 carbon atoms, and still more preferably from 4 to 6 carbon atoms), an amino group, an alkylamino group, an alkylsulfonyl group, or a halogen atom, and m and n each independently represents an integer of from 0 to 4 (preferably from 0 to 2, and more preferably 0 or 1). The number of carbon atoms in the alkyl chain of the alkylamino group and the alkylsulfonyl group is preferably from 1 to 4. It is preferable that R³ and R⁴ be each independently an alkyl group having from 1 to 4 carbon atoms (more preferably 1 or 2 carbon atoms), an alkoxy group having from 4 to 12 carbon atoms (more preferably from 4 to 8 carbon atoms, and still more preferably from 4 to 6 carbon atoms), or a chlorine atom.

The anthracene derivative can be suitably used as a sensitizer with high absorption at the i-line that makes it possible to increase the Tg and hardness and reduce thermal swelling rate of the resist film. However, the alkoxy group in the anthracene derivative is easily oxidizable, and there is a concern that the storage stability may be lowered. In particular, when used in combination with a carbonyl group-containing solvent, the anthracene derivative is easily decomposed by a peroxide derived from the solvent. By using a compound represented by the formula (1) that includes an alkyl group having 4 or more carbon atoms or an aryl group having from 6 to 10 carbon atoms as R¹ and R², a structure is obtained in which the alkoxy group or aryloxy group is susceptible to oxidation. Therefore, it is possible to provide a photosensitive resin composition having excellent storage stability.

The alkyl groups of R¹ and R² may have a substituent or may be unsubstituted. Examples of the substituent include a halogen atom such as chlorine, bromine and fluorine, an alkyl group having an ether bond, a hydroxy group, an aryl group, and the like. The alkyl group may be branched and may also include multiple bonds in the alkyl chain.

The amount of the anthracene derivative, which is the component (c), is preferably from 0.001 to 30 parts by mass, more preferably from 0.1 to 30 parts by mass, even more preferably 0.5 to 10 parts by mass, still more preferably from 1 to 8 parts by mass, and particularly preferably from 2 to 5 parts by mass with respect to 100 parts by mass of the solid fraction of the epoxy resin, which is the component (a). Within the above ranges, the photoreactivity of the cationic polymerization initiator is improved.

Organic Solvent (d)

The photosensitive resin composition comprises an organic solvent as the component (d). From the viewpoint of the solubility of the epoxy resin and the coatability of the coating solvent of the resist material, the organic solvent has a carbonyl group. The organic solvent is exemplified by at least one selected from the group consisting of ketone compounds such as methyl isobutyl ketone (MIBK), cyclic ketone compounds such as cyclohexanone, ester compounds such as propylene glycol monomethyl ether acetate (PGMEA), lactone compounds such as γ-butyrolactone, carbonic acid ester compounds such as diethyl carbonate, and cyclic carbonic acid ester compounds such as propylene carbonate.

Oxidation is likely to advance in the following order: ketone>cyclic ketone>ester>lactone>carbonic acid ester>cyclic carbonate ester, and there is a concern that a peroxide may be generated during storage and the anthracene derivative may be decomposed. Therefore, it is preferable to use at least one selected from the group consisting of ester compounds, lactone compounds, carbonic acid ester compounds and cyclic carbonic acid ester compounds. More preferably, a carbonic acid ester compound or a cyclic carbonate compound is selected. When these organic solvents have an alkyl group or an alkoxy group, a halogen atom such as chlorine, bromine or fluorine, an alkyl group having an ether bond, a hydroxy group, an aryl group or the like may be included as a substituent. Further, the alkyl group may be branched, and multiple bonds may be contained in the alkyl chain.

The amount of the organic solvent (d) in the photosensitive resin composition is not particularly limited but is preferably from 30 to 500 parts by mass, more preferably from 50 to 300 parts by mass, and even more preferably from 100 to 200 parts by mass with respect to 100 parts by mass of the solid fraction of the epoxy resin.

Other Components

In addition to the components shown above, the photosensitive resin composition can comprise a sensitizing aid, a basic substance such as an amine, an acid generator that generates weakly acidic (pKa=−1.5 to 3.0) toluenesulfonic acid, a silane coupling agent, and the like for the purpose of improving photolithographic performance, adhesion performance, and the like.

The photosensitive resin composition preferably comprises a sensitizing aid. Examples of the sensitizing aid include compounds that improve the energy conversion efficiency of light-absorbed anthracene derivatives. Examples of commercially available products include “ANTHRACURE UVS-2171” manufactured by Kawasaki Kasei Chemicals Ltd. The amount of the sensitizing aid is not particularly limited but is preferably from 0.5 to 30 parts by mass, and more preferably from 1 to 10 parts by mass with respect to 100 parts by mass of the solid fraction of the epoxy resin.

The photosensitive resin composition preferably comprises a basic substance or an acid generator, and more preferably comprises an acid generator. An acid generator that generates weakly acidic (pKa=−1.5 to 3.0) toluenesulfonic acid is preferable. Examples of commercially available products include “TPS-1000” (trade name) manufactured by Midori Kagaku Co., Ltd. The amount of the acid generator is not particularly limited but is preferably from 0.5 10 parts by mass, and more preferably from 1 to 5 parts by mass with respect to 100 parts by mass of the solid fraction of the epoxy resin.

The photosensitive resin composition preferably comprises a silane coupling agent. Preferred examples thereof include a silane coupling agent having an epoxy group or a glycidyl group. Examples of commercially available products include “SILQUEST A-187” (trade name) manufactured by Momentive Performance Materials Inc. The amount of the silane coupling agent is not particularly limited but is preferably from 1 to 30 parts by mass, and more preferably from 5 to 15 parts by mass with respect to 100 parts by mass of the solid fraction of the epoxy resin.

Manufacture of Shaped Product

The present disclosure provides a shaped product made of a cured product of the photosensitive resin composition.

A method for manufacturing the shaped product preferably comprises a step of pattern-exposing the photosensitive resin composition and a step of curing an exposed portion that has been pattern-exposed and then removing an unexposed portion to obtain the shaped product. In the pattern exposure step, the photosensitive resin composition is i-line irradiated. The shaped product is, for example, a cured product of the photosensitive resin composition obtained by i-line irradiation.

Further, the present disclosure provides a structure in which a shaped product is formed on a substrate, the shaped product being a cured product of the photosensitive resin composition.

Further, a method for manufacturing a structure including a shaped product preferably comprises a step of laminating the photosensitive resin composition on a substrate, a step of pattern-exposing the photosensitive resin composition, and a step of curing an exposed portion that has been pattern-exposed and then removing an unexposed portion to obtain a structure in which a cured product of the photosensitive resin composition, which is the shaped product, is formed on the substrate, wherein in the pattern exposure step, the photosensitive resin composition is irradiated with i-line radiation.

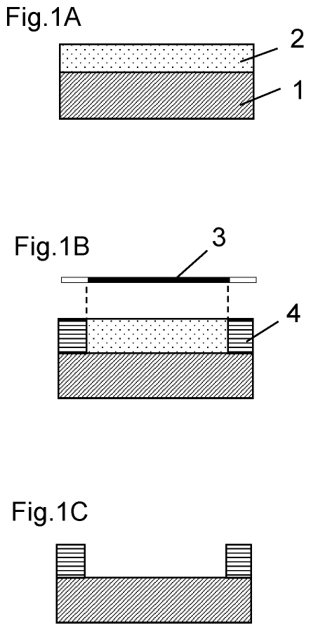

The following is an example of a method for manufacturing a shaped product using a photosensitive resin composition. A photosensitive resin composition (1) indicated by 2 is laminated on a substrate 1 by coating or the like with a spin coating method, a slit coating method, or the like, and dried (FIG. 1A). Subsequently, the photosensitive resin composition (1) indicated by 2 is pattern-exposed with i-line radiation through a mask 3, and then the exposed portion is further cured by heat treatment (FIG. 1B). The mask 3 is obtained by forming a light-shielding film such as a chrome film according to a pattern on a substrate made of a material such as glass or quartz that transmits i-line radiation. As the exposure device, a projection exposure device having an i-line as a light source such as an i-line exposure stepper (trade name, manufactured by Canon Inc.) can be used. Then, by removing the unexposed portion of the photosensitive resin composition (1) indicated by 2 with a solvent such as PGMEA, a shaped product (cured product) 4 can be obtained on the substrate (FIG. 1C).

Application to Inkjet Recording Head

The shaped product can be exemplified by a liquid discharge head. That is, the photosensitive resin composition can be applied to a liquid discharge head. The liquid discharge head comprises, for example, a substrate, a flow path forming member that is provided on the substrate and forms a liquid flow path, and a discharge port forming member that is provided on the flow path forming member and has a discharge port for discharging a liquid. The flow path forming member is a cured product of the photosensitive resin composition. The discharge port forming member may be a cured product of the photosensitive resin composition as well.

The thickness of the liquid discharge head or the shaped product in the direction perpendicular to the surface of the substrate on which the photosensitive resin composition is laminated may be determined, as appropriate, by the discharge design of the liquid discharge head or the design of the shaped product and is preferably from 3.0 to 25.0 μm.

As an example, a method for manufacturing an inkjet recording head, which is a form of a liquid ejection head, will be described hereinbelow. The scope of application of the shaped product is not limited to this. A method for manufacturing a liquid discharge head comprising at least a substrate, a flow path forming member that is provided on the substrate and forms a liquid flow path, and a discharge port forming member that is provided on the flow path forming member and has a discharge port for discharging a liquid, the method for manufacturing comprising following steps at least: a step of laminating the photosensitive resin composition on the substrate, a step of pattern-exposing the photosensitive resin composition, and a step of curing an exposed portion that has been pattern-exposed, and then removing an unexposed portion to form the flow path forming member on the substrate, wherein the photosensitive resin composition is i-line irradiated in the pattern exposure step.

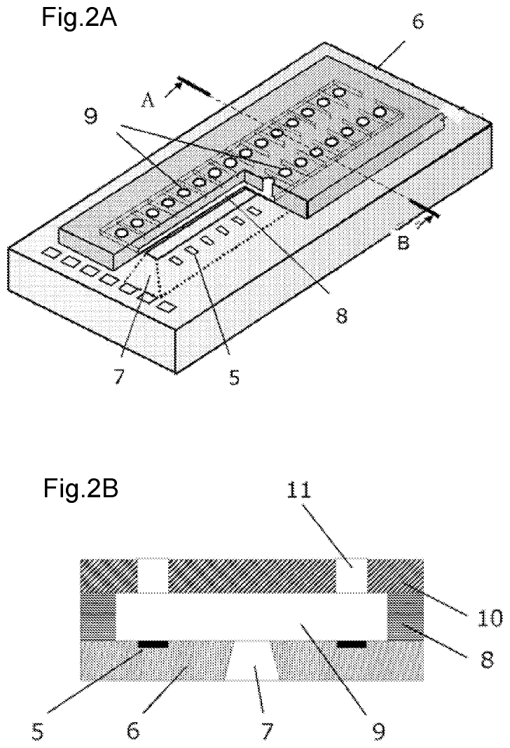

FIG. 2A is a schematic perspective view showing an example of an inkjet recording head obtained by applying the method for manufacturing a shaped product according to the present embodiment. Further, FIG. 2B is a schematic cross-sectional view showing a cross section of the inkjet recording head in A-B in FIG. 2A.

The inkjet recording head shown in FIGS. 2A and 2B has a substrate 6 in which energy generating elements 5 that generate energy to be used for ejecting ink are arranged at a predetermined pitch. A supply unit 7 that supplies ink is opened in the substrate 6 between two rows of energy generating elements 5. An ink flow path 9 is formed on the substrate 6 by a flow path forming member 8. The flow path forming member 8 corresponds to the shaped products according to the present disclosure. Discharge ports 11 are formed in a discharge port forming member 10. Further, the discharge port forming member 10 can also correspond to the shaped products. The flow path forming member 8 and the discharge port forming member 10 may be integrated.

In the inkjet recording head shown in FIGS. 2A and 2B, energy generated by the energy generating elements 5 is given to the ink supplied from the supply unit 7 through the flow path 9, so that the ink is discharged as droplets through the discharge ports 11.

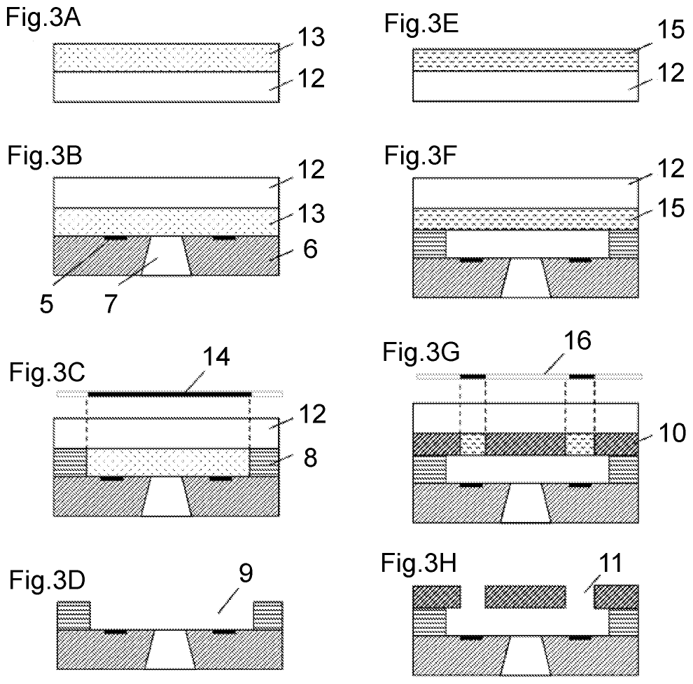

FIGS. 3A to 3H are schematic cross-sectional views showing an example of a method for manufacturing an inkjet recording head in which a shaped product according to the present embodiment is adopted.

First, the photosensitive resin composition (1) indicated by 13 according to the present disclosure is coated onto a PET film 12 by a spin coating method, a slit coating method, or the like, and dried by heating to produce a dry film (FIG. 3A). The obtained dry film is transferred onto the inorganic substrate 6 having the energy generating elements 5 and the ink supply unit 7 (FIG. 3B). The photosensitive resin composition (1) indicated by 13 is pattern-exposed through a mask 14 having a flow path pattern, and further heat-treated to cure the exposed portion, and then the unexposed portion of the photosensitive resin composition (1) indicated by 13 is removed with an organic solvent to form the flow path 9 (FIGS. 3C and 3D).

Subsequently, a photosensitive resin composition (2) indicated by 15 is coated onto the PET film 12 and dried by heating to prepare a dry film, which is transferred onto the flow path forming member 8 (FIGS. 3E and 3F). The photosensitive resin composition (2) indicated by 15 is pattern-exposed through a mask 16 having a discharge port pattern, and further heat-treated to cure the exposed portion, and then the unexposed portion of the photosensitive resin composition (2) indicated by 15 is removed with an organic solvent to form the discharge ports 11 (FIGS. 3G and 3H). The masks 14 and 16 have a light-shielding film such as a chrome film formed on a substrate in accordance with a pattern of discharge ports or the like, the substrate being made of a material such as glass or quartz that transmits i-line radiation.

As the exposure device, a projection exposure device having an i-line light source such as an i-line exposure stepper (trade name, manufactured by Canon Inc.) can be used. The amount of exposure is not particularly limited and may be controlled, as appropriate, according to the photosensitive resin composition used. The exposure amount is, for example, preferably about from 500 to 20,000 J/m², and more preferably about from 5000 to 15,000 J/m².

The photosensitive resin composition (2) indicated by 15 may be the above-mentioned photosensitive resin composition according to the present disclosure or may be another photosensitive resin composition.

By performing each of the above steps, it becomes possible to manufacture an inkjet recording head having excellent adhesion between the substrate 6 and the flow path forming member 8.

### EXAMPLES

The present invention is more specifically described here below using examples. The present invention is not limited by the examples that follow. The number of parts in the following formulations is on a mass basis in all instances unless specifically indicated otherwise.

### Examples 1 to 37

The components shown in Tables 1 to 6 were mixed to prepare the photosensitive resin composition (1) of Examples 1 to 37. After storing at 25° C. for 30 days, shaped products were produced on the substrate by the steps shown in FIGS. 1A to 1C as follows. The numerical value of each component in the table is the number of parts. The product names in the table are as described in the main text of the description.

The photosensitive resin compositions (1) of Examples 1 to 37 were coated onto the substrate 1 by a spin coating method and dried by heat treating at 90° C. for 5 min (FIG. 1A). Subsequently, the photosensitive resin composition 2 was pattern-exposed through the mask 3 and further heat-treated to cure the exposed portion. Here, in the exposure machine, irradiation with light was performed at an exposure amount of 12,000 J/m² by using an i-line exposure stepper (manufactured by Canon Inc.) (FIG. 1B). Then, the unexposed portion of the photosensitive resin composition 2 was removed by PGMEA to form the shaped product 4 on the substrate (FIG. 1C). The thickness of the shaped product 4 was 10 μm.

### Examples 38 to 40

An inkjet recording head was produced by the steps shown in FIGS. 3A to 3H.

First, the photosensitive resin compositions (1) having the compositions shown in Table 1 (Example 2), Table 2 (Example 12), and Table 6 (Example 37) were stored at 25° C. for 30 days. Then, each photosensitive resin composition (1) was coated onto the PET film 12 by a spin coating method and dried by heat treating at 90° C. for 5 min to obtain a dry film (FIG. 3A). The obtained dry film was transferred onto the silicon substrate 6 provided with the energy generating elements 5 and the supply unit 7 (FIG. 3B).

Subsequently, as shown in FIG. 3C, the photosensitive resin composition (1) indicated by 13 was pattern-exposed through the mask 14 having a flow path pattern, and further heat-treated to cure the exposed portion. Here, in the exposure machine, irradiation with light was performed at an exposure amount of 12,000 J/m² by using the i-line exposure stepper (manufactured by Canon Inc.). Then, the unexposed portion of the photosensitive resin composition (1) indicated by 13 was removed by PGMEA to form the flow path forming member 8 and the flow path 9 (FIG. 3D). The thickness of the flow path forming member 8 was 10 μm.

Then, the photosensitive resin composition (2) indicated by 15 having the composition shown in Table 8 was coated onto the PET film 12 and dried by heat treating at 90° C. for 5 min to obtain a dry film 15 (FIG. 3E). The photosensitive resin composition (2) of each composition shown in Table 8 was used in the combinations shown in Table 9.

The obtained dry film 15 was transferred onto the flow path forming member 8. The dry film 15 was pattern-exposed through the mask 16 having a discharge port pattern and then heat-treated to cure the exposed portion. After that, the unexposed portion of the dry film 15 was removed by PGMEA to form the discharge port forming member 10 and the discharge ports 11, thereby producing an inkjet discharge head (FIGS. 3G and 3H). The exposure in FIG. 3G was performed at an exposure amount of 1100 J/m² using the same device as described above.

### Comparative Examples 1 to 4

Shaped products were formed in the same manner as in Example 1, except that the compositions obtained by mixing the components shown in Table 7 were used as the photosensitive resin composition (1).

### Comparative Examples 5 to 8

Inkjet ejection heads were produced in the same manner as in Example 38, except that the compositions obtained by mixing the components shown in Table 7 as the photosensitive resin composition (1) were used in the combinations shown in Table 9.

Evaluation Method 1

The curability of the shaped products produced by the methods of Examples 1 to 37 and Comparative Examples 1 to 4 was evaluated. Regarding the curability, the film thickness of the shaped product 4 before and after curing was measured, and the evaluation was performed in the following three stages on the basis of the amount of change.
Curability A: change rate is less than 3%
Curability B: change rate is 3% or more and less than 5%
Curability C: change rate is 5% or more

Evaluation Method 2

The absorption spectra of the photosensitive resin compositions of Examples 1 to 37 and Comparative Examples 1 to 4 at the i-line were measured before and after storage. The storage conditions were 25° C. for 30 days. The absorption spectra were measured with a spectrophotometer U-3300 (manufactured by Hitachi High-Tech Science Corporation). The rate of change in absorbance at the i-line before and after the storage was checked, and the following evaluations were performed.
Storage stability A: change rate is less than 1%
Storage stability B: change rate is 1% or more and less than 3%
Storage stability C: change rate is 3% or more

Evaluation Method 3

The print quality was evaluated using the inkjet ejection heads produced in Examples 38 to 40 and Comparative Examples 5 to 8. Using a Canon printer MB5330, a continuous printing test was performed in an environment of 30° C. and 80% RH, and the presence or absence of dot misdirection was visually checked. In the continuous printing test, 100 sheets with solid images on A4 paper were continuously printed. Here, A corresponds to a case where the print quality did not change and no misdirection occurred from the initial stage, B corresponds to a case where the print misdirection was less than 1%, and C corresponds to a case where the print misdirection was 1% or more.

The printing misdirection (%) was calculated as follows.

Print misdirection=(misdirection area/solid print area)×100

The misdirection area is the area of the portion that became blank due to the misdirection, and this area was observed with an electron microscope and visually determined.

Evaluation Result 1 and 2

As shown in Tables 1 to 6, with the method according to the Examples, it was possible to provide a photosensitive resin composition having excellent curability and storage stability. Meanwhile, in Comparative Example 1, since the anthracene derivative was not added, the reactivity of the cationic polymerization initiator was insufficient and the curability was lowered. In Comparative Examples 2 to 4, although the curability was ensured, the anthracene derivative was decomposed during storage, and the absorbance at the i-line was decreased.

Evaluation Result 3

Next, the evaluation results of the inkjet ejection heads will be described. In the method according to the Examples, it was possible to provide an inkjet ejection head having excellent ejection durability. In particular, in Example 40, no degradation of print quality was observed and good results were obtained even after 100 sheets printed with solid images. This is because the composition of Example 37 optimized for use in the inkjet ejection head was used as the photosensitive resin composition (1).

Specifically, the composition was such that the patterning accuracy was improved by the acid generator, and the adhesion to the substrate was improved by the silane coupling agent. Meanwhile, in the inkjet ejection heads of Comparative Examples 5 to 8 manufactured by the method according to the Comparative Examples, misdirection occurred after 100 sheets printed with solid images, and the ejection durability was insufficient.

TABLE 1
Photosensitive resin composition (1)

| | | Product name | Example | | | | | | | | | |
|---|---|---|---|---|---|---|---|---|---|---|---|---|
| Component | | (compound name) | 1 | 2 | 3 | 4 | 5 | 6 | 7 | 8 | 9 | 10 |
| (a) Epoxy resin | Tri- or | EPICLON N695 | 100 | 100 | 100 | 100 | 100 | 100 | 100 | 100 | 100 | 100 |
| | higher | | | | | | | | | | | |
| | functional | | | | | | | | | | | |
| (b) Cationic | SbF₆ ⁻ salt | CPI-110A | 0.05 | 3 | 10 | 30 | 40 | 3 | 3 | 3 | 3 | 3 |
| polymerization | | | | | | | | | | | | |
| initiator | | | | | | | | | | | | |
| (c) Anthracene derivative | | 9,10-Di-n- | 3 | 3 | 3 | 3 | 3 | 0.05 | 3 | 10 | 30 | 40 |
| | | butoxyanthracene | | | | | | | | | | |
| (d) Organic | Ester | PGMEA | 150 | 150 | 150 | 150 | 150 | 150 | 150 | 150 | 150 | 150 |
| solvent | | | | | | | | | | | | |

| | | | | | | | | | | |
|---|---|---|---|---|---|---|---|---|---|---|
| Curability | B | A | A | A | A | B | A | A | A | A |
| Storage stability | A | A | A | A | A | A | A | A | A | A |

TABLE 2
Photosensitive resin composition (1)

| | | Product name | Example | | | |
|---|---|---|---|---|---|---|
| Component | | (compound name) | 11 | 12 | 13 | 14 |
| (a) Epoxy resin | Tri- or | EPLICLON N695 | | | 100 | 100 |
| | higher | 157S70 | 100 | | | |
| | functional | EHPE3150 | | 100 | | |
| | Bifunctional | jER1007 | | | 200 | |
| | | jER1009F | | | | 200 |
| (b) Cationic | SbF₆ ⁻ salt | CPI-110A | 3 | 1.5 | 10 | 10 |
| polymerization | | | | | | |
| initiator | | | | | | |
| (c) Anthracene derivative | | 9,10-Di-n- | 3 | 0.3 | 10 | 10 |
| | | butoxyanthracene | | | | |
| (d) Organic | Ester | PGMEA | 150 | 150 | 150 | 150 |
| solvent | | | | | | |

| | | | | |
|---|---|---|---|---|
| Curability | A | A | A | A |
| Storage stability | A | A | A | A |

TABLE 3
Photosensitive resin composition (1)

| | | Product name | Example | | | | | | |
|---|---|---|---|---|---|---|---|---|---|
| Component | | (compound name) | 15 | 16 | 17 | 18 | 19 | 20 | 21 |
| (a) Epoxy resin | Tri- or | EPLICLON N695 | 100 | 100 | 100 | 100 | 100 | 100 | 100 |
| | higher | | | | | | | | |
| | functional | | | | | | | | |
| (b) Cationic | B(C₆F₅)₄ ⁻ salt | DTS-200 | 5.2 | | | | | | |
| polymerization | PF₆ ⁻ salt | DTS-102 | | 2.6 | | | | | |
| initiator | SbF₆ ⁻ salt | SP-172 | | | 7.3 | | | | |
| | PF₆ ⁻ salt | Omnicat250 | | | | 1.8 | | | |
| | (Rf)nPF₆₋ₙ ⁻ salt | CPI-410S | | | | | 3.0 | | |
| | B(C₆F₅)₄ ⁻ salt | WPI-124 | | | | | | 12.8 | |
| | SbF₆ ⁻ salt | WPI-116 | | | | | | | 8.4 |
| (c) Anthracene derivative | | 9,10-Di-n- | 3 | 3 | 3 | 3 | 3 | 3 | 3 |
| | | butoxyanthracene | | | | | | | |
| (d) Organic | Ester | PGMEA | 150 | 150 | 150 | 150 | 150 | 150 | 150 |
| solvent | | | | | | | | | |

| | | | | | | | |
|---|---|---|---|---|---|---|---|
| Curability | A | A | A | A | A | A | A |
| Storage stability | A | A | A | A | A | A | A |

TABLE 4
Photosensitive resin composition (1)

| | | Product name | Example | | | | | | |
|---|---|---|---|---|---|---|---|---|---|
| Component | | (compound name) | 22 | 23 | 24 | 25 | 26 | 27 | 28 |
| (a) Epoxy resin | Tri- or | EPICLON N695 | 100 | 100 | 100 | 100 | 100 | 100 | 100 |
| | higher | | | | | | | | |
| | functional | | | | | | | | |
| (b) Cationic | SbF₆ ⁻ salt | CPI-110A | 3 | | | | | | |
| polymerization | | | | | | | | | |
| initiator | | | | | | | | | |
| (c) Anthracene derivative | | 9,10-Di- | 3 | | | | | | |
| | | isobutoxyanthracene | | | | | | | |
| | | 9,10-Bis- | | 3 | | | | | |
| | | (n-pentyloxy) | | | | | | | |
| | | anthracene | | | | | | | |
| | | 9,10-Bis- | | | 3 | | | | |
| | | (n-decyloxy) | | | | | | | |
| | | anthracene | | | | | | | |
| | | 9,10- | | | | 3 | | | |
| | | Diphenoxyanthracene | | | | | | | |
| | | 1-Chloro-9,10-di-n- | | | | | 3 | | |
| | | butoxyanthracene | | | | | | | |
| | | 2-Ethyl-9,10-di-n- | | | | | | 3 | |
| | | butoxyanthracene | | | | | | | |
| | | 1,4,9,10-Tetra-n- | | | | | | | 3 |
| | | butoxyanthracene | | | | | | | |
| (d) Organic | Ester | PGMEA | 150 | 150 | 150 | 150 | 150 | 150 | 150 |
| solvent | | | | | | | | | |

| | | | | | | | |
|---|---|---|---|---|---|---|---|
| Curability | A | A | A | A | A | A | A |
| Storage stability | A | A | A | A | A | A | A |

TABLE 5
Photosensitive resin composition (1)

| | | Product name | Example | | | | | |
|---|---|---|---|---|---|---|---|---|
| Component | | (compound name) | 29 | 30 | 31 | 32 | 33 | 34 |
| (a) Epoxy resin | Tri- or | EPICLON N695 | 100 | 100 | 100 | 100 | 100 | 100 |
| | higher | | | | | | | |
| | functional | | | | | | | |
| (b) Cationic | SbF₆ ⁻ salt | CPI-110A | 3 | 3 | 3 | 3 | 3 | 3 |
| polymerization | | | | | | | | |
| initiator | | | | | | | | |
| (c) Anthracene derivative | | 9,10-Di-n- | 3 | 3 | 3 | 3 | 3 | 3 |
| | | butoxyanthracene | | | | | | |
| (d) Organic | Ketone | MIBK | 150 | | | | | |
| solvent | Cyclic ketone | Cyclohexanone | | 150 | | | | |
| | Ester | PGMEA | | | 150 | | | |
| | Lactone | γ-Butyrolactone | | | | 150 | | |
| | Carbonic | Carbonic | | | | | 150 | |
| | acid ester | acid ester | | | | | | |
| | Cyclic | Propylene | | | | | | 150 |
| | carbonic | carbonate | | | | | | |
| | acid ester | | | | | | | |

| | | | | | | |
|---|---|---|---|---|---|---|
| Curability | A | A | A | A | A | A |
| Storage stability | B | B | A | A | A | A |

TABLE 6
Photosensitive resin composition (1)

| | | Product name | Example | | |
|---|---|---|---|---|---|
| Component | | (compound name) | 35 | 36 | 37 |
| (a) Epoxy resin | Tri-or higher functional | EPICLON N695 | 100 | 100 | 100 |
| | Bifunctional | jER1009F | | 200 | 200 |
| (b) Cationic | SbF₆⁻ salt | CPI-110A | 3 | 10 | 10 |
| polymerization initiator | | | | | |
| (c) Anthracene derivative | | 9,10-Di-n-butoxyanthracene | 3 | 10.63 | 10.63 |
| Sensitizing aid | | UVS-2171 | 3 | | |
| Silane coupling agent | | A-187 | | 10.71 | 10.71 |
| Acid generator | | TPS-1000 | | | 2.5 |
| (d) Organic solvent | Ester | PGMEA | 150 | 500 | 500 |

| | | | |
|---|---|---|---|
| Curability | A | A | A |
| Storage stability | A | A | A |

TABLE 7
Photosensitive resin composition (1)

| | | Product name | Comparative Example | | | |
|---|---|---|---|---|---|---|
| Component | | (compound name) | 1 | 2 | 3 | 4 |
| (a) Epoxy resin | Tri- or | EPICLON N695 | 100 | 100 | 100 | 100 |
| | higher | | | | | |
| | functional | | | | | |
| (b) Cationic | SbF₆ ⁻ salt | CPI-110A | 3 | 3 | 3 | 3 |
| polymerization | | | | | | |
| initiator | | | | | | |
| (c) Anthracene derivative | | 9,10- | | 3 | | |
| | | Dimethoxyanthracene | | | | |
| | | 9,10- | | | 3 | |
| | | Diethoxyanthracene | | | | |
| | | 9,10-Di-n- | | | | 3 |
| | | propyloxyanthracene | | | | |
| (d) Organic | Ester | PGMEA | 150 | 150 | 150 | 150 |
| solvent | | | | | | |

| | | | | |
|---|---|---|---|---|
| Curability | C | A | A | A |
| Storage stability | C | C | C | C |

TABLE 8
Photosensitive resin composition (2)

| | Product name | Composition | |
|---|---|---|---|
| Component | (compound name) | 1 | 2 |
| Epoxy resin | 157S70 | 100 | |
| | EHPE3150 | | 100 |
| Cationic | CPI-410S | 3 | 1 |
| polymerization | | | |
| initiator | | | |
| Solvent | Xylene | | 40 |
| | PGMEA | 150 | |

TABLE 9
Liquid discharge head

| | Example | | | Comparative Example | | | |
|---|---|---|---|---|---|---|---|
| Component | 38 | 39 | 40 | 5 | 6 | 7 | 8 |
| Photosensitive resin | Example 2 | Example 12 | Example 37 | Comparative | Comparative | Comparative | Comparative |
| composition (1) | | | | Example 1 | Example 2 | Example 3 | Example 4 |
| Photosensitive resin | 1 | 2 | 1 | 1 | 1 | 1 | 1 |
| composition (2) | | | | | | | |
| Printed quality | B | B | A | C | C | C | C |

The anthracene derivatives used are shown hereinbelow.

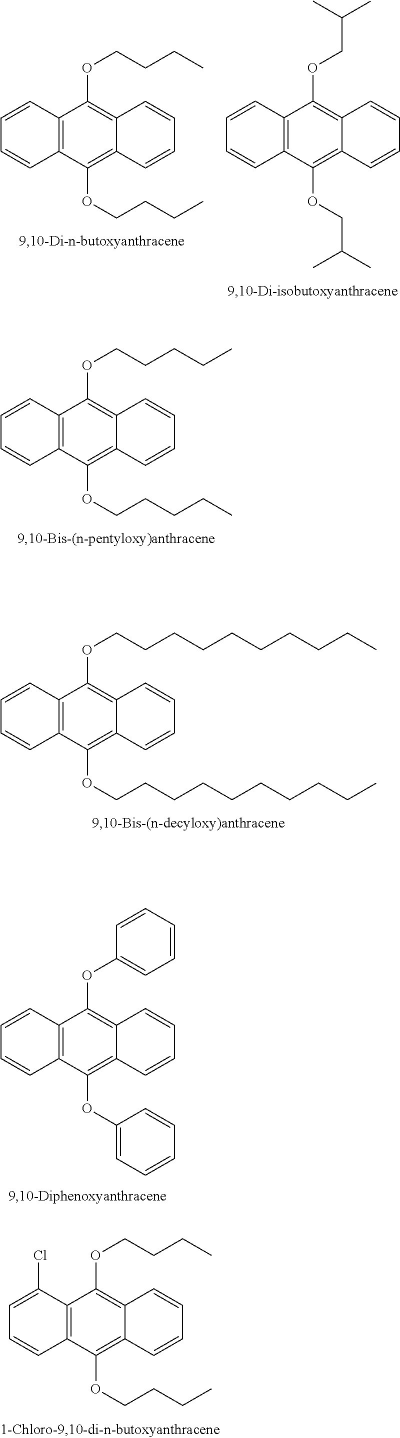 [SMILES: CCCCOc1c2ccccc2c(OCCCC)c2ccccc12 ; CC(C)COc1c2ccccc2c(OCC(C)C)c2ccccc12 ; CCCCCOc1c2ccccc2c(OCCCCC)c2ccccc12 ; CCCCCCCCCCOc1c2ccccc2c(OCCCCCCCCCC)c2ccccc12 ; c1ccc(Oc2c3ccccc3c(Oc3ccccc3)c3ccccc23)cc1 ; CCCCOc1c2ccccc2c(OCCCC)c2c(Cl)cccc12]

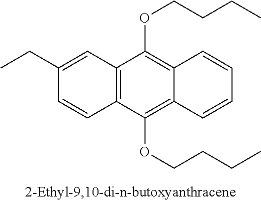 [SMILES: CCCCOc1c2ccccc2c(OCCCC)c2cc(CC)ccc12]

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. This application claims the benefit of Japanese Patent Application No. 2021-123199, filed Jul. 28, 2021, which is hereby incorporated by reference herein in its entirety.

What is claimed is:

1. A photosensitive resin composition comprising:
(a) an epoxy resin,
(b) a cationic polymerization initiator,
(c) an anthracene derivative, and
(d) an organic solvent having a carbonyl group, wherein
the anthracene derivative (c) comprises at least one selected from the group consisting of compounds represented by a following formula (1). 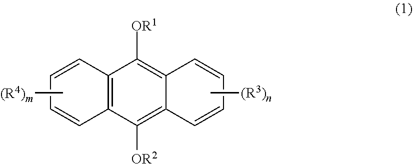
(In the formula (1), R¹ and R² each independently represents an alkyl group having 4 or more carbon atoms or an aryl group having 6 to 10 carbon atoms, R³ and R⁴ each independently represents an alkyl group, an alkoxy group having 4 or more carbon atoms, an amino group, an alkylamino group, an alkylsulfonyl group, or a halogen atom, and m and n each independently represents an integer of 0 to 4).

2. The photosensitive resin composition according to claim 1, wherein in the formula (1), R¹ and R² each independently represents an alkyl group having 4 to 18 carbon atoms or a phenyl group, and the R³ and R⁴ each independently represents an alkyl group having 1 to 4 carbon atoms, an alkoxy group having 4 to 12 carbon atoms, or a halogen atom.

3. The photosensitive resin composition according to claim 1, wherein the epoxy resin (a) comprises a tri- or higher functional epoxy resin.

4. The photosensitive resin composition according to claim 1, wherein the epoxy resin (a) is at least one selected from the group consisting of an epoxy resin having an alicyclic skeleton, an epoxy resin having a bisphenol skeleton, an epoxy resin having a phenol-novolac skeleton, an epoxy resin having a cresol-novolak skeleton, an epoxy resin having a norbornene skeleton, an epoxy resin having a terpene skeleton, an epoxy resin having a dicyclopentadiene skeleton, and an epoxy resin having an oxycyclohexane skeleton.

5. The photosensitive resin composition according to claim 1, wherein the epoxy resin (a) comprises a tri- or higher functional epoxy resin and a bifunctional epoxy resin.

6. The photosensitive resin composition according to claim 1, wherein the cationic polymerization initiator (b) comprises at least one selected from the group consisting of a sulfonium salt compound and an iodonium salt compound.

7. The photosensitive resin composition according to claim 1, wherein the cationic polymerization initiator (b) comprises at least one selected from the group consisting of SbF₆⁻, AsF₆⁻, PF₆⁻, (Rf)ₙPF₆₋ₙ⁻ (Rf is a perfluoroalkyl group), BF₄⁻, and B(C₆F₅)₄⁻.

8. The photosensitive resin composition according to claim 1, wherein an amount of the cationic polymerization initiator (b) is 0.1 to 30 parts by mass with respect to 100 parts by mass of the solid fraction of the epoxy resin.

9. The photosensitive resin composition according to claim 1, wherein an amount of the anthracene derivative (c) is 0.1 to 30 parts by mass with respect to 100 parts by mass of the solid fraction of the epoxy resin.

10. The photosensitive resin composition according to claim 1, wherein the organic solvent (d) having a carbonyl group comprises at least one selected from the group consisting of an ester compound, a lactone compound, a carbonic acid ester compound and a cyclic carbonic acid ester compound.

11. The photosensitive resin composition according to claim 1, wherein the photosensitive resin composition further comprises a sensitizing aid.

12. The photosensitive resin composition according to claim 1, wherein the photosensitive resin composition further comprises a basic substance or an acid generator.

13. The photosensitive resin composition according to claim 1, wherein the photosensitive resin composition further comprises a silane coupling agent.

14. A shaped product composed of a cured product of the photosensitive resin composition according to claim 1.

15. A method for manufacturing a shaped product, the method comprising:
a step of pattern-exposing the photosensitive resin composition according to claim 1, and
a step of curing an exposed portion that has been pattern-exposed and then removing an unexposed portion to obtain the shaped product, wherein
in the pattern exposure step, the photosensitive resin composition is irradiated with i-line radiation.

16. A method for manufacturing a structure comprising a shaped product, the method comprising:
a step of laminating a photosensitive resin composition on a substrate,
a step of pattern-exposing the photosensitive resin composition, and
a step of curing an exposed portion that has been pattern-exposed and then removing an unexposed portion to obtain a structure in which a cured product of the photosensitive resin composition, which is the shaped product, is formed on the substrate, wherein
the photosensitive resin composition is the photosensitive resin composition according to claim 1, and
in the pattern exposure step, the photosensitive resin composition is irradiated with i-line radiation.

17. A liquid discharge head comprising a substrate, a flow path forming member that is provided on the substrate and forms a liquid flow path, and a discharge port forming member that is provided on the flow path forming member and has a discharge port for discharging a liquid, wherein
the flow path forming member is a cured product of the photosensitive resin composition according to claim 1.

18. A method for manufacturing a liquid discharge head comprising at least a substrate, a flow path forming member that is provided on the substrate and forms a liquid flow path, and a discharge port forming member that is provided on the flow path forming member and has a discharge port for discharging a liquid, the method for manufacturing comprising at least following steps: a step of laminating a photosensitive resin composition on the substrate,
a step of pattern-exposing the photosensitive resin composition, and
a step of curing an exposed portion that has been pattern-exposed, and then removing an unexposed portion to form the flow path forming member on the substrate, wherein
the photosensitive resin composition is the photosensitive resin composition according to claim 1, and
in the pattern exposure step, the photosensitive resin composition is irradiated with i-line radiation.
